(19) United States
(12) Patent Application Publication
(10) Pub. No.: US 2024/0332448 A1
(43) Pub. Date: Oct. 3, 2024

(54) METHOD FOR APPLYING AN ELECTRICAL CONNECTION MATERIAL OR FLUX MATERIAL TO A COMPONENT

(71) Applicant: ams-OSRAM International GmbH, Regensburg (DE)

(72) Inventors: Sebastian Wittmann, Regenstauf (DE); Daniel Leisen, Regensburg (DE); Matthias Hofmann, Regensburg (DE)

(21) Appl. No.: 18/580,115

(22) PCT Filed: Jul. 20, 2022
(86) PCT No.: PCT/EP2022/070422

§ 371 Date: Jan. 17, 2024

(30) Foreign Application Priority Data
Jul. 23, 2021 (DE) 102021119155.6

(51) Int. Cl. H01L 33/00; B23K 1/20; B23K 101/38

(52) U.S. Cl. CPC H01L 33/005; B23K 1/203; B23K 2101/38; H01L 2933/0066

(57) ABSTRACT

In an embodiment a method includes providing a first carrier on which an electrical connection material or a flux material is arranged, providing a second carrier on which at least one optoelectronic component is arranged, positioning the first carrier relative to the second carrier such that the electrical connection material or the flux material is facing at least one electrical connection surface and is spaced from the at least one electrical connection surface, pulse irradiating the first carrier with laser light such that at least areas of the electrical connection material or the flux material are detached from the first carrier and fall onto the at least one electrical connection surface of the optoelectronic component, wherein the electrical connection material or the flux material is arranged in a structured manner on the first carrier, and wherein the first carrier is irradiated over a large area with the laser light in order to detach at least regions of the structured electrical connection material or the flux material from the first carrier.

### CROSS-REFERENCE TO RELATED APPLICATIONS

This patent application is a national phase filing under section 371 of PCT/EP2022/070422, filed Jul. 20, 2022, which claims the priority of German patent application 10 2021 119 155.6, filed Jul. 23, 2021, each of which is incorporated herein by reference in its entirety.

### TECHNICAL FIELD

The present invention relates to a method for applying an electrical connection material or flux material to at least one electrical connection surface of an optoelectronic component.

### BACKGROUND

For the electrical contacting or connection of optoelectronic components, an electrical connection material can be applied to the electrical connection surfaces of the optoelectronic components, for example, in order to apply the optoelectronic components to a receiver component or substrate and to connect them electrically to this. It may be necessary, for example, to apply a flux material to the electrical connection surfaces of the optoelectronic components in addition to the electrical connection material in order to enable the best possible electrical contact between the electrical connection surfaces and the electrical connection material.

At present, electrical connection materials or flux materials are often applied to the electrical connection surface of the optoelectronic component by means of stencil printing or jetting. However, these methods cannot be applied to the electrical connection surfaces with unlimited accuracy or with an unlimited small size or volume. Particularly in the case of optoelectronic components with an edge length of less than 100 μm or electrical connection surfaces with a lateral expansion of less than 50 μm, it is often not possible to achieve the desired accuracy with which an electrical connection material or flux material is applied to the electrical connection surfaces of the optoelectronic component using the methods mentioned. For electrically conductive materials, there is a particular risk that an electrical connection material applied using such a method can trigger a short circuit between the electrical connection surfaces of the optoelectronic component.

Although there are some methods, such as galvanization or evaporation processes, which can be used to achieve a corresponding level of accuracy, such methods are usually very complex and cost-intensive.

There is therefore a need to counteract the aforementioned problems and to specify an improved method for applying an electrical connection material or flux material to at least one electrical connection surface of an optoelectronic component, which can be carried out both simply and at reduced cost.

### SUMMARY

A method according to the proposed principle for applying an electrical connection material, in particular an electrically conductive connection material, or flux material to at least one electrical connection surface of an optoelectronic component comprises the steps:
providing a first carrier on which the electrical connection material or flux material is arranged;
providing a second carrier on which the at least one optoelectronic component is arranged;
positioning the first carrier relative to the second carrier such that the electrical connection material or flux material is positioned facing and spaced from the at least one electrical connection surface; and
pulsed irradiation of the first carrier with laser light in such a way that at least areas of the electrical connection material or flux material are detached from the first carrier and fall onto the at least one electrical connection surface of the optoelectronic component.

The process according to the proposed principle can, for example, be similar to a laser-induced forward transfer process (abbreviation: LIFT). In this process, a pulsed laser beam is used as a driving force to transfer material from a donor substrate to a receiver substrate. In contrast to the conventional or known processes mentioned above, such as stencil printing or jetting, the process according to the proposed principle can be used to transfer significantly finer or smaller structures and volumes of the electrical connection material or flux material. In addition, there is the advantage that an improved accuracy or precision can be achieved by means of the process, by means of which the electrical connection material or flux material is applied to the at least one electrical connection surface of the optoelectronic component.

Furthermore, in contrast to electroplating and evaporation processes, the process according to the proposed principle does not require photoresist, a mask, or structuring or processing of the electrical connection material on the electrical connection surfaces of the optoelectronic component. The shape and the volume of the electrical connection material or flux material to be transferred, on the other hand, can already be determined by the arrangement of the electrical connection material or flux material on the first carrier or by selective or area-by-area irradiation of the first carrier with laser light.

In particular, this has the advantage that the electrical connection material or flux material can also be easily applied subsequently to existing components or assemblies or even to sensitive components or assemblies using the method according to the proposed principle, since there is no need to process the electrical connection material or flux material on the connection surfaces of the components or assemblies.

In some embodiments, the electrical connection material comprises at least one of the following materials:
a sintered material;
an electrically conductive adhesive;
an anisotropic conductive adhesive;
a solder; and
a solder-glue hybrid system.

In particular, the electrical connection material can be formed by a sinter paste, an electrically conductive adhesive or a solder paste. The electrical connection material is characterized in particular by the fact that it has electrically conductive properties. Furthermore, the electrical connection material can be characterized by the fact that it can be used to connect two components together. This can be achieved by heating and/or melting the electrical connection material and/or by exerting pressure on the electrical connection material or the components to be connected to each other with the electrical connection material. In some aspects, an electrically conductive adhesive comprises, for example, silver particles and an adhesive matrix material in which the particles are disposed.

In some embodiments, the first carrier for at least the laser light is essentially transparent. Essentially transparent can mean that at least light in the wavelength range of the laser light is not or only barely absorbed or reflected by the material of the first carrier, but is transmitted through it without major losses. For example, the first carrier can be formed by a glass carrier or glass wafer or a transparent film.

In some embodiments, the second carrier is formed by a wafer composite or an artificial wafer. In particular, a wafer composite is an arrangement comprising a plurality of unpackaged semiconductor chips. This can be, for example, a semiconductor wafer, in particular an uncut semiconductor wafer, which has a plurality of individual semiconductor chips, in some aspects, the wafer composite is a carrier to which a plurality of uncut but already separated semiconductor chips is applied in order to enable further processing thereof. In this case, it is also referred to as an artificial wafer or sorted sheet. The semiconductor chips are preferably fixed to the carrier, for example by gluing them to the carrier or encapsulating them with a casting compound such as silicone. The semiconductor chips can also be inserted into receptacles in the carrier for fixing.

In some embodiments, the electrical connection material or flux material fallen from the first carrier onto the second carrier comprises a volume of 5 μm³ to 10000 μm³, in particular up to 100000 μm³. In particular, the electrical connection material or flux material that has fallen onto the second carrier has structures of less than or equal to 100 μm or less than or equal to 50 μm on the at least one electrical connection surface. For example, the electrical connection material or flux material that has fallen onto the second carrier has structures with a width and/or length and/or height of less than or equal to 50 μm on the at least one electrical connection surface. For example, the electrical connection material or flux material that has fallen onto the second carrier can cover an area of up to 50×50 μm² or larger on the at least one electrical connection surface and have a thickness or height of up to 30 μm.

In some embodiments, the optoelectronic component has two electrical connection surfaces that are at most 50 μm apart. A partial area of the electrical connection material or flux material is applied to each of the electrical connection surfaces separately from one another, in particular electrically separately. The separate sub-areas of the electrical connection material or flux material do not touch each other, but are arranged at a distance from each other in such a way that there is no risk of a short circuit between the sub-areas during operation of the optoelectronic component.

In some embodiments, the electrical connection material or flux material is arranged over a large area on the first carrier. The areas of the electrical connection material or flux material that are detached from the first carrier are selectively irradiated with laser light and thereby fall in the direction of the second carrier onto the at least one electrical connection surface of the optoelectronic component.

Alternatively, however, it is also possible for the electrical connection material or flux material to be arranged in a structured manner on the first carrier and for the first carrier to be irradiated with laser light over a large area. The irradiated structured areas of the electrical connection material or flux material are thereby detached from the first carrier and fall in the direction of the second carrier onto the at least one electrical connection surface of the optoelectronic component. In particular, the electrical connection material or flux material can be structured or arranged on the first carrier in such a way that the structures on the first carrier are coordinated with the areas of electrical connection surfaces on the second carrier on which the electrical connection material or flux material is to be arranged. In particular, a high degree of accuracy or precision can thus be achieved, by means of which the electrical connection material or flux material can be applied to the at least one electrical connection surface of the optoelectronic component.

In some embodiments, the optoelectronic device comprises at least one LED or at least one LED chip. The LED or LED chip may in particular also be referred to as a micro LED, also referred to as μLED, or μLED chip, in particular in the event that it has edge lengths in a range from 100 μm to 10 μm. The LED or LED chip can also be referred to as a mini-LED or mini-LED chip, especially if it has edge lengths in the range from 250 μm to 100 μm.

In some embodiments, the optoelectronic component is part of a wafer array with a plurality of optoelectronic components grown on a wafer. The optoelectronic components can be present on the wafer in the form of unhoused semiconductor chips. Unhoused means that the chip has no housing around its semiconductor layers, such as a “chip die”. In some embodiments, unhoused may mean that the chip is free of any organic material. Thus, the unhoused device does not contain any organic compounds that contain carbon in covalent bonding.

In some embodiments, the first carrier has at least one cavity in which the electrical connection material or flux material is arranged. In particular, the first carrier may also have a plurality of identical or differently shaped cavities in which the electrical connection material or flux material is arranged. In particular, the shape and size of the cavity can define a volume of the electrical connection material or flux material that is to be transferred to the second carrier or to the electrical connection surfaces. For example, differently sized and differently shaped cavities can be used to transfer differently sized and differently shaped volumes of the electrical connection material or flux material to different electrical connection surfaces.

In some embodiments, the at least one cavity is provided by means of etching or laser drilling. The first carrier can, for example, be prepared or processed in a processing step in such a way that it has at least one cavity at a previously defined position or a plurality of cavities at previously defined positions.

In some embodiments, the electrical connection material or flux material is provided by means of doctor blades in the at least one cavity or in the plurality of cavities. In this case, the electrical connection material or flux material is applied to the first carrier in the region of the at least one cavity or over a large area, and excess material that does not remain in the at least one cavity is scraped off by means of a doctor blade.

In some embodiments, the electrical connection material or flux material is flush with a surface of the first carrier. This may be the case, for example, due to the stripping of the excess material.

In some embodiments, a release layer is arranged between the first carrier and the electrical connection material or flux material. This release layer can be in the form of a sacrificial layer, for example, which is melted or vaporized by the laser light. This makes it possible, for example, for the electrical connection material or flux material to detach from the first carrier in an improved manner.

In some embodiments, the electrical connection material forms a redistribution layer (abbreviation: RDL) on the at least one electrical connection surface. A redistribution or rewiring layer is an additional metal layer on the at least one electrical connection surface of the optoelectronic component, which makes the electrical connection surface available at other points of the optoelectronic component in order to enable better access to the electrical connection surface if required. A redistribution or rewiring layer can also allow the optoelectronic device to be bonded from different locations on the optoelectronic device. This simplifies the bonding of the optoelectronic component in some applications. Another example of the use of a redistribution or rewiring layer is the distribution of the electrical connection surfaces on the optoelectronic component. In the case of solder balls applied to the electrical connection surfaces, the thermal load on the optoelectronic component can be better distributed during assembly.

In some embodiments, the method further comprises baking, sintering and/or re-melting the electrical connection material. In particular, such a step occurs after the electrical connection material is disposed on the at least one electrical connection surface.

In some embodiments, electrical connection material is transferred in a stacked manner to the at least one electrical connection surface by means of the method. For this purpose, the first carrier can be moved laterally relative to the electrical connection surface after the electrical connection material has been transferred to the at least one electrical connection surface, and electrical connection material is again released from the first carrier by means of pulsed laser light so that it falls onto the electrical connection material already arranged on the electrical connection surface. This step can be repeated several times so that, for example, different heights of the electrical connection material can be achieved on different electrical connection surfaces.

In some embodiments, the method further comprises the steps of:
rotate the second carrier;
placing the second carrier opposite a third carrier such that the electrical connection material or flux material is facing and spaced from the third carrier; and
pulsed irradiation of the second carrier with laser light in such a way that the optoelectronic component falls in the direction of the third carrier.

This allows the optoelectronic component, or in the case of several optoelectronic components, the several or a number of optoelectronic components to be detached from the second carrier using the same principle as described above (LIFT method) and transferred to a third carrier.

In some embodiments, the second carrier is essentially transparent for at least the laser light. Essentially transparent can mean that at least light in the wavelength range of the laser light is not or only barely absorbed or reflected by the material of the second carrier, but is transmitted through it without major losses. For example, the second carrier can be formed by a glass carrier or glass wafer or a transparent film.

In some embodiments, a release layer is arranged between the second carrier and the optoelectronic component. This release layer can be in the form of a sacrificial layer, for example, which is melted or vaporized by the laser light. This makes it possible, for example, for the optoelectronic component to detach from the second carrier in an improved manner.

### BRIEF DESCRIPTION OF THE DRAWINGS

In the following, embodiments of the invention are explained in more detail with reference to the accompanying drawings.

FIG. 1 shows a method for applying an electrical connection material or flux material to at least one electrical connection surface of an optoelectronic component according to some aspects of the proposed principle;

FIG. 2 shows a further method of applying an electrical bonding material or flux material to at least one electrical connection surface of an optoelectronic device according to some aspects of the proposed principle; and

FIG. 3 shows a step of a further method for applying an electrical connection material or flux material to at least one electrical connection surface of an optoelectronic component according to some aspects of the proposed principle.

### DETAILED DESCRIPTION OF ILLUSTRATIVE EMBODIMENTS

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

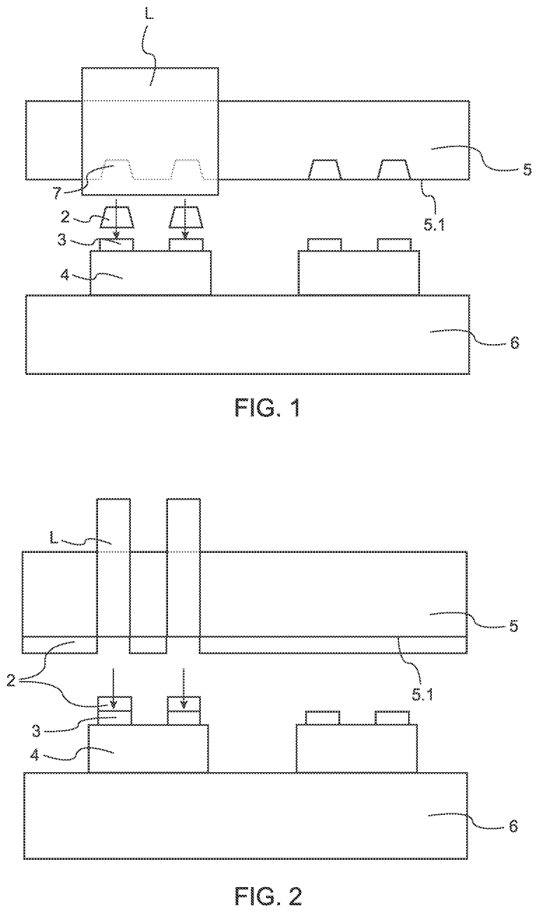

FIG. 1 shows a method for applying an electrical connection material 2 or flux material to at least one electrical connection surface 3 of an optoelectronic component 4. For this purpose, a first carrier 5 is provided, on which the electrical connection material 2 or flux material is arranged. In the example shown in FIG. 1, this is an electrical connection material 2, such as a solder paste, a sintered material or an electrically conductive adhesive, which is arranged on the first carrier 5. The first carrier 5 has cavities 7 that are filled with the electrical connection material 2. In the case shown, the cavities 7 are trapezoidal in shape, but any other shape and configuration of the cavities is also conceivable.

The cavities 7 of the first carrier 5 are filled with the electrical connection material 2 in such a way that the electrical connection material 2 is flush with a surface 5.1 of the first carrier 5. In particular, the cavities can be filled with the electrical connection material 2 using a doctor blade process, for example.

Furthermore, a second carrier 6 is provided, on which at least one optoelectronic component 4 is arranged. In the case shown, two optoelectronic components 4 are arranged next to each other and at a distance from each other on the second carrier 6. The optoelectronic components 4 each have electrical connection surfaces 3, by means of which the optoelectronic components 4 can be supplied with electrical energy for operating the optoelectronic components 4.

The first carrier 5 is positioned above the second carrier 6 in such a way that the electrical connection material 2 faces the electrical connection surfaces 3 and is arranged at an angle to them. There is therefore an air gap between the electrical connection material 2 and the electrical connection surfaces 3.

In particular, the first carrier 5 is placed above the second carrier in such a way that at least one cavity 7 filled with the electrical connection material 2 is arranged directly above an electrical connection surface 3. In the case shown, the first carrier 5 is structured or the first carrier 5 has several cavities 7 arranged in such a way that the electrical connection material 2 is arranged on the first carrier 5 in each case exactly above the electrical connection surfaces 3 of the optoelectronic components 4.

By means of a pulsed laser beam or laser light L, the first carrier 5 is irradiated in such a way that at least areas of the electrical connection material 2 are detached from the first carrier 5 and fall onto the underlying electrical connection surfaces 3 of the optoelectronic component 4. In particular, exactly one area of the electrical connection material 2 is released from the first carrier 5 per light pulse and falls onto an underlying electrical connection surface 3 of the optoelectronic component 4. Contrary to the example shown, it is also possible for the first carrier 5 to be irradiated with laser light L over a large area, so that essentially all predefined areas of the electrical connection material 2 are released from the first carrier 5 and fall in the direction of the second carrier 6.

Such a process can, for example, be similar to a laser-induced stock transfer process (LIFT). In order to prevent tilting or twisting of the electrical connection material 2 detached from the first carrier 5 and falling in the direction of the second carrier 6, the process shown can be carried out in a vacuum chamber, for example.

The electrical connection material 2, which is detached from the first carrier 5 and falls in the direction of the second carrier 6, strikes the electrical connection surfaces 3 of the optoelectronic components 4 and remains there or adheres to the electrical connection surfaces 3.

FIG. 2 shows a further embodiment example of a method for transferring an electrical connection material 2 or flux material to electrical connection surfaces 3 of an optoelectronic component 4. In contrast to the method shown in FIG. 1, however, the electrical connection material 2 is not arranged in cavities of the first carrier 5, but over a large area on a surface 5.1 of the first carrier 5. In particular, the electrical connection material can completely cover the surface 5.1 of the first carrier 5.

Only areas of the electrical connection material 2 are transferred to the electrical connection surfaces 3 by irradiating the first carrier with laser light L in a targeted manner and only selectively or locally. As a result, an electrical connection material 2 is only detached from the first carrier 5 in the areas of the first carrier 5 in which the first carrier is irradiated with laser light L.

The electrical connection material 2 detached from the first carrier falls onto the electrical connection surfaces 3 as described in the previous case and remains or adheres there.

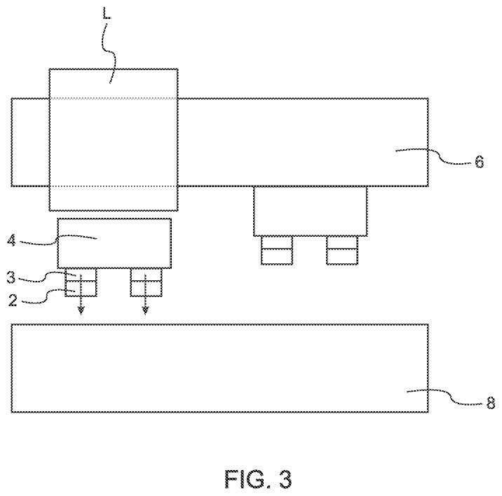

FIG. 3 shows a further step of a method for applying an electrical connection material 2 or flux material to at least one electrical connection surface 3 of an optoelectronic component 4. The second carrier 6 is rotated and placed above a third carrier 8 in such a way that the electrical connection material 2 faces the third carrier 8 and is arranged at a distance from it.

Subsequently, the second carrier 6 is irradiated with a pulsed laser light L such that one or more optoelectronic devices 4 fall towards the third carrier. As a result, the optoelectronic component 4, or in the case of several optoelectronic components, the several or a number of optoelectronic components can be detached from the second carrier 6 using the same principle as described above (LIFT method) and transferred to a third carrier 8.

As shown in the figure, the optoelectronic component(s) 4 come into contact with the electrical connection material 2 on the third carrier and remain or adhere there. The third carrier can, for example, have electrical connection surfaces or contact pads onto which the optoelectronic components 4 fall. The optoelectronic component(s) 4 can be electrically connected to the third carrier 8 by means of the electrical connection material 2.

1.-16. (canceled)

17. A method for applying an electrical connection material or a flux material to an electrical connection surface of at least one optoelectronic component, the method comprising:
providing a first carrier on which the electrical connection material or the flux material is arranged;
providing a second carrier on which the at least one optoelectronic component is arranged;
positioning the first carrier relative to the second carrier such that the electrical connection material or the flux material is facing the at least one electrical connection surface and is spaced from the at least one electrical connection surface; and
pulse irradiating the first carrier with laser light such that at least areas of the electrical connection material or the flux material are detached from the first carrier and fall onto the at least one electrical connection surface of the optoelectronic component,
wherein the electrical connection material or the flux material is arranged in a structured manner on the first carrier, and
wherein the first carrier is irradiated over a large area with the laser light in order to detach at least regions of the structured electrical connection material or the structured flux material from the first carrier.

18. The method according to claim 17, wherein the electrical connection material comprises at least one of the following materials:
a sintered material,
an electrically conductive adhesive,
an anisotropic conductive adhesive,
a solder, or
a solder-glue hybrid system.

19. The method according to claim 17, wherein the first carrier is substantially transparent for at least the laser light.

20. The method according to claim 17, wherein the second carrier is formed by a wafer composite or an artificial wafer.

21. The method according to claim 17, wherein the electrical connection material or the flux material fallen from the first carrier onto the second carrier comprises a volume of 5 μm³ to 10000 μm³.

22. The method according to claim 17,
wherein the optoelectronic component comprises two electrical connection surfaces which are spaced apart by at most 50 μm, and
wherein a partial region of the electrical connection material or the flux material is applied to each of the electrical connection surfaces.

23. The method according to claim 17,
wherein the electrical connection material or the flux material is arranged over a large area on the first carrier, and
wherein the areas of the electrical connection material or the flux material, which are detached from the first carrier, are selectively irradiated with laser light.

24. The method according to claim 17, wherein the optoelectronic component is a μ-LED chip.

25. The method according to claim 17, wherein the first carrier comprises at least one cavity in which the electrical connection material or the flux material is arranged.

26. The method according to claim 25, wherein the at least one cavity is formed by etching or laser drilling.

27. The method according to claim 25, wherein the electrical connection material or the flux material is provided by doctor blading in the at least one cavity.

28. The method according to claim 25, wherein the electrical connection material or the flux material is flush with a surface of the first carrier.

29. The method according to claim 17, wherein a release layer is arranged between the first carrier and the electrical connection material or the flux material.

30. The method according to claim 17, further comprising baking, sintering or re-melting the electrical connection material.

31. The method according to claim 17, further comprising:
rotating the second carrier;
placing the second carrier opposite a third carrier such that the electrical connection material or the flux material is arranged facing the third carrier and being spaced from the third carrier; and
pulse irradiating the second carrier with the laser light such that the optoelectronic component falls in a direction of the third carrier.

32. The method according to claim 31, wherein the second carrier is substantially transparent for at least the laser light.
